(19) United States
(12) Patent Application Publication
(10) Pub. No.: US 2006/0212977 A1
(43) Pub. Date: Sep. 21, 2006

(54) Characterizing electron beams

(76) Inventors: Charles Otis, Corvallis, OR (US); John G. Bamber, Corvallis, OR (US)

Correspondence Address: HEWLETT-PACKARD DEVELOPMENT COMPANY;Intellectual Property Administration, P.O. Box 272400, Fort Collins, CO, 80527-2400, US

(21) Appl. No.: 11/081,982

(22) Filed: Mar. 16, 2005

(51) Int. Cl. H01L 51/40

(52) U.S. Cl. 977/844; 438/99

(57) ABSTRACT

A nanowire e-beam or characterizing device is provided. In one implementation, the nanowire that has at least one cross-sectional dimension within the nano-scale dimension.

### TECHNICAL FIELD

This invention relates to electron beams, and more particularly to characterization of electron beams.

### BACKGROUND

Electron beams (e-beams) are used in a variety of applications including certain computer memory devices, and e-beam lithography processing techniques. E-beam lithography is an etching process used in the production of some components of a semiconductor, superconductor, or other material. Using current techniques, a focused e-beam can have a diameter down to the order of nanometers or tens of nanometers. Such minutely focused e-beams are difficult to characterize and/or measure spatially or temporally.

In one aspect, e-beams are characterized or measured in e-beam based memory storage devices. Such e-beam characterizing or measuring devices may require an instrument to determine the location and spectral density of an e-beam. Increasing the precision with which the e-beam can be measured may improve the storage density of e-beam memory devices that can be incorporated into any given e-beam memory circuit. In another aspect, an improvement in the cross-sectional measurement and power can permit a more controlled application of e-beam to nano-scale workpieces such as semiconductor substrates. Accordingly, there is a need for improved techniques for characterizing an e-beam with the capability of being focused down to nanometer (or tens of nanometers) diameters.

### BRIEF DESCRIPTION OF THE DRAWINGS

The same numbers are used throughout the drawings to reference like features and components:

FIG. 1 is a top elevational view of one embodiment of a nanowire electron beam (e-beam) characterizing device having a single nanowire;

FIG. 2 is a graphical output plotting current output versus distance from the embodiment of the nanowire e-beam characterizing device after scanning a substantially Gaussian e-beam;

FIG. 3 is a top elevational view of another embodiment of a nanowire e-beam characterizing device having an array of nanowires;

FIG. 4 is a top elevational view of another embodiment of a nanowire e-beam characterizing device having an array of nanowires;

FIG. 5 is a top elevational view of yet another embodiment of a nanowire e-beam characterizing device having an array of nanowires;

FIG. 6 is a top elevational view of another embodiment of a nanowire e-beam characterizing device having an array of microdots;

FIG. 7 is a flow chart of one embodiment of process that can be used to produce nanowire e-beam characterizing devices; and

FIG. 8 is a block diagram of one embodiment of computer/controller that runs a process portion which can be used to fabricate nanowire e-beam characterizing devices.

### DETAILED DESCRIPTION

This disclosure provides a variety of embodiments of a nanowire electron-beam (e-beam) characterizing device 100. The e-beam characterizing device 100 performs a variety of metrology and calibration functions including measuring the dimensions of, and the intensity within, an e-beam. Certain embodiments of the nanowire e-beam characterizing device 100 are capable of characterizing, spatially or temporally, a focused electron beam whose diameter is on the order of nanometers or tens of nanometers. While this disclosure is directed to an “e-beam” characterizing device 100, ions (e.g., gas ions) could also be measured and characterized in a similar manner. As such, the term “e-beam” within this disclosure also applies to, and is intended to include, ion beams.

Certain embodiments of the nanowire e-beam characterizing device 100 can measure e-beam spot size and intensity. One embodiment of the nanowire e-beam characterizing device 100 as described in this disclosure is applicable to e-beam based storage devices that utilize an instrument that can measure in real time the X location or the X-Y location (depending on the embodiment) and/or stability of the centroid of the focused e-beam. The ability of the nanowire e-beam characterizing device 100 to measure the spatial profile (e.g., considering such factors as the e-beam location, the spot size stability, the centroid stability, and the current stability, etc.) can be utilized to enhance a memory scheme based on e-beam write, read, and erase processes. This is especially applicable with nano-scale devices since the present disclosure characterizes e-beams with nanowires.

The different embodiments of the nanowire e-beam characterizing device 100 include one or more nanowires 102 arranged in different configurations as described herein. In this disclosure, the term “nanowires” 102 is means to include nanowires, nanotubes, nanodots, and any other nanostructure having at least one dimension that is in the nano-scale (i.e., less than 100 nanometers). The configurations of the nanowires 102 in the nanowire e-beam characterizing device 100 include, but are not limited to, single nanowires 102, parallel (one dimensional) arrays of nanowires, rectangular arrays of nanowires, and arrays of nanodots as described in this disclosure.

Each one of the nanowires 102 that is included in the nanowire e-beam characterizing device 100 has a smaller width and/or pitch than the diameter of the focused electron beam. In one embodiment, a Faraday probe forms an active portion of the e-beam characterizing device. Faraday probes (not shown) are commercially available and include a current loop with a high permeability ferrite core in the center of the current loop. The Faraday probes provide an output indicative of the current produced by charged particles traversing, e.g., a chamber.

An electrically conductive nanowire, an array of individually addressable nanowires, or a crossed array of separated nanowires are used to measure electric current produced by the electron beam as the electron beam impinges on the nanowires. Each nanowire (whether in the single nanowire or the multiple nanowire array configuration) has a width that is a small fraction of the e-beam spot size which it is to characterize in order to effectively measure the e-beam impinging on the wire. This fraction of the e-beam spot size is a function of the level of accuracy for the measurements. The more accurate the measurement, the smaller the fraction should be. Conversely, the measuring device could actually be on the order of, or larger than the e-beam or the gas ion beam, in which case a deconvolution of the measured result would also be required.

One embodiment of the nanowire e-beam characterizing device 100 includes a single one of the nanowires 102. Other disclosed embodiments have a plurality of nanowires (arranged in arrays) and associated components.

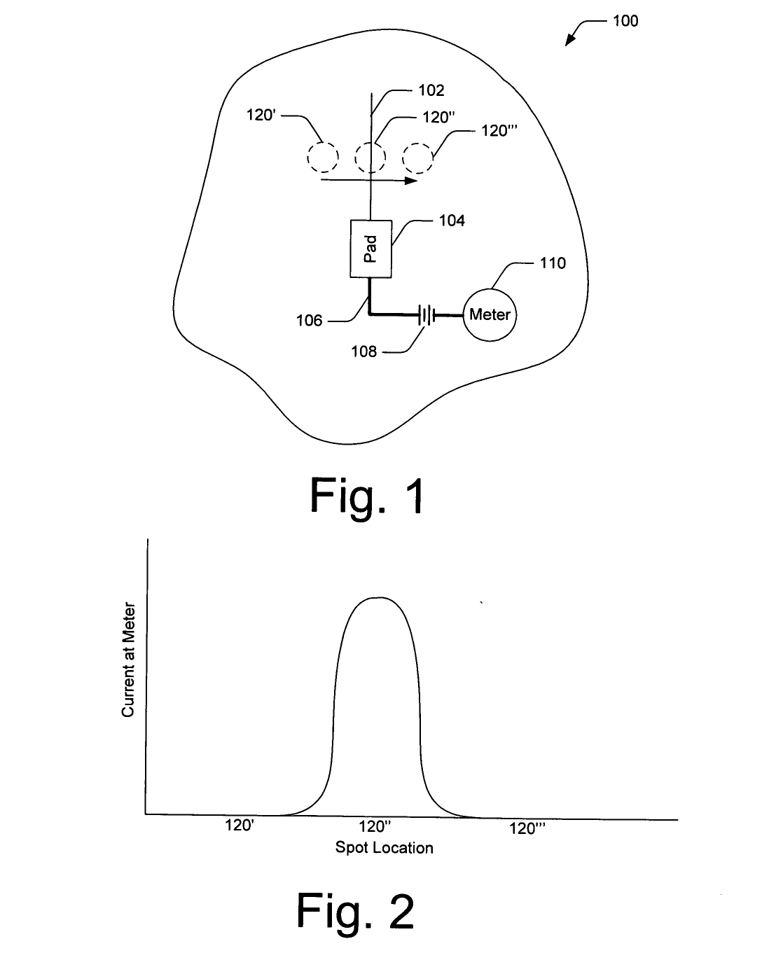

The embodiment of nanowire e-beam characterizing device 100 shown in FIG. 1 includes the nanowire 102, a pad 104, an electrical conductor 106, a power source 108 (i.e., any voltage source that could be either AC or DC), and an electrometer 110. The pad 104 provides electrical conduction between the nanowire 102 and the electrical conductor 106. In general, the combination of the nanowire 102, the pad 104, and the electrical conductor 106 acts as a combined electrical conductor whose electric potential can be gradually varied as different intensities of e-beams are applied to the nanowire 102.

The power source provides the voltage bias to collect the electrons. The electrometer 110 determines the electric current flowing through (or the electric voltage being applied across) the nanowire 102. The electric current flowing through the nanowire 102 is a function of the voltage that is applied across the nanowire 102 based on Ohm's Law. The current flowing through the nanowire 102 varies based on the number of electrons imparted from the e-beam to the nanowire.

An e-beam spot is illustrated as being scanned from left to right as shown in FIG. 1 through successive e-beam spot positions 120′, 120″, and 120′″. When the e-beam is centered over the nanowire, as shown in e-beam spot position 120″, then the number of electrons transmitted from the e-beam via the e-beam spot 120 to the nanowire 102 is at an increased level. When the e-beam is not centered over the nanowire, as shown in 120′ and 120′″, then the number of electrons transmitted from the e-beam via the e-beam spot 120 to the nanowire 102 is at a diminished level compared to the increased level. Since the width of the nanowire 102 is considerably less than the cross-sectional dimension of the e-beam spot 120, the nanowire can precisely measure the strength and dimension of the e-beam as it scans across the nanowire 102 (or the nanowire scans across the e-beam in another embodiment). In this disclosure, stating that the e-beam spot is being displaced relative to the nanowire 102 can indicate either that the e-beam spot is being displaced relative to the nanowire 102, that the nanowire is being scanned across the e-beam spot, or a combination thereof.

The cross-sectional dimension of a nanowire is sufficiently small to function as a scanning slit. The current density profile, as the e-beam travels across the nanowire (or vice versa), can be mapped out as illustrated in FIG. 2. As the e-beam spot is scanned perpendicularly to the axial direction of the nanowire (such as represented by the positions 120′, 120″, and 120′″ in FIGS. 1 and 2), the current measured on the wire will follow the current density—spot size product which produces a curve that is related to the current intensity of the wire being measured. For an e-beam spot 120 having a substantially Gaussian current intensity across its width, the electrometer 110 will output an approximately Gaussian curve as illustrated in FIG. 2. One embodiment of the circuit used to measure the current for the single wire embodiment of the nanowire e-beam characterizing device 100 is illustrated in FIG. 1.

Single wire embodiments of nanowire e-beam characterizing devices 100 can effectively characterize the e-beam. Certain other embodiments of the nanowire e-beam characterizing device 100 that include, for example, arrays of nanowires can also be used. A variety of arrays of nanowires for the nanowire e-beam characterizing device 100 are therefore described in this disclosure that include, for example, parallel nanowires, crossed grids of nanowires, and arrays of nanodots.

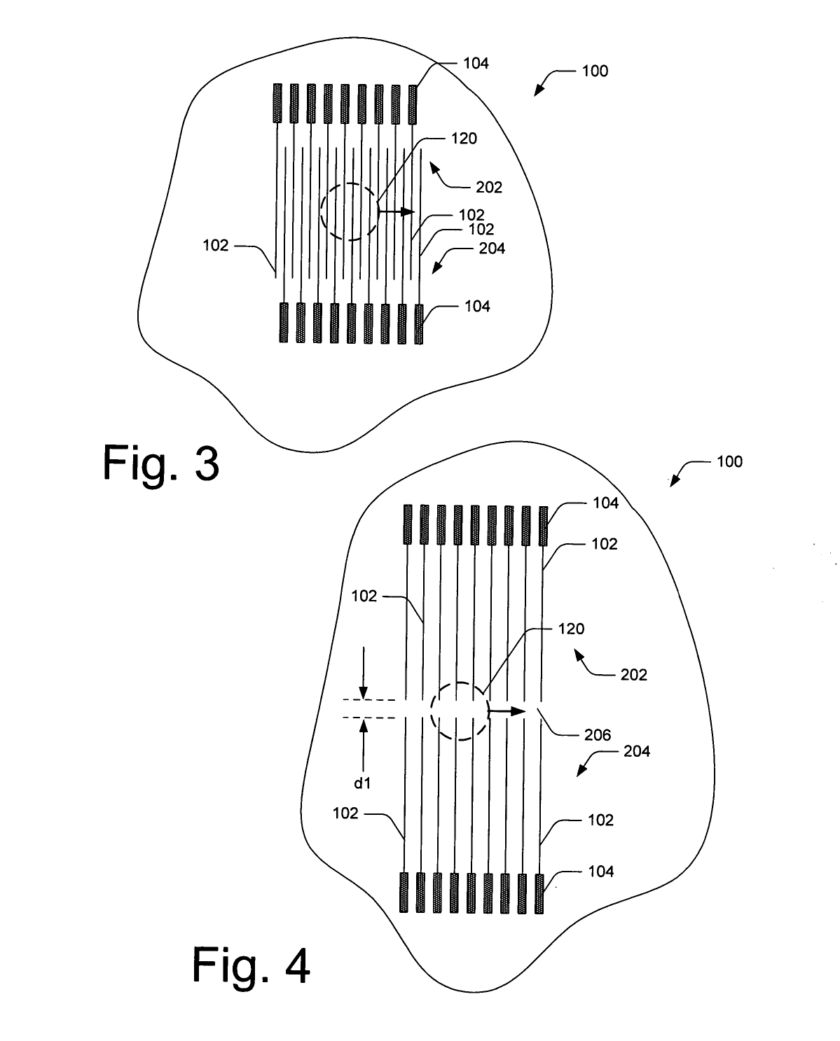

One embodiment of the nanowire e-beam characterizing device 100 that includes two array sets 202, 204 of nanowires is illustrated in FIGS. 3 and 4. Each of the two array sets 202 and 204 include one array of substantially parallel nanowires. Each array set is oriented in opposed directions, such that the nanowires 102 in the array set 202 are directed as downwardly (as interpreted in FIG. 3) from their corresponding pads 104, while the nanowires 102 in the array set 204 are directed as upward (as interpreted in FIG. 3) from their corresponding pads 104. A considerable vertical overlap is shown in FIG. 3 between the nanowires in the array set 202 and the nanowires in the array set 204. No such vertical overlap is shown in FIG. 4 in which the array sets 202 and 204 are vertically separated. As such, it is to be understood that a wide variety of relative configurations can be provided between multiple array sets.

For simplicity, the components 106, 108, and 110 shown in the embodiment of nanowire e-beam characterizing device 100 shown in FIG. 1 are not shown in the more complex nanowire e-beam characterizing device as shown in FIGS. 3, 4, 5, and 6. There are a variety of electronic configurations for the nanowire e-beam characterizing device that are envisioned to be within the scope of the present disclosure.

In one embodiment, the signal from each wire is monitored by an individual electrometer channel. In another embodiment, a plurality of the signals from each one of the multiple wires can be multiplexed using known electronic multiplexing systems that will not be further detailed herein. The combined data from each wire can be combined to produce a histogram of the current for each nanowire's X position. In this disclosure, the term “X” direction or position refers to the respective direction or position as taken along the horizontal axis as it appears on the paper. The term “Y” direction or position refers to the respective direction or position as taken along the vertical axis as it appears on the paper. As such, the terms “X” and “Y” are arbitrary when related to an actual product. In general, though, those embodiments having nanowires (and nanowire arrays) that are arranged only along a single axis are considered as extending along the Y axis and detect e-beam position and motion in the X direction.

Yet another embodiment of the nanowire e-beam characterizing device 100 is shown in FIG. 4. The FIG. 4 embodiment includes array sets 202 and 204 of nanowires that are arranged in a similar manner to that described relative to the FIG. 3 embodiment, except that there is no overlap between the upwardly extending set of nanowires and the downwardly extending set of nanowires. In the FIG. 4 embodiment of the nanowire e-beam characterizing device 100, the ends of the nanowires 102 of the array set 202 are separated by distance d1 from the ends of the nanowires 102 of the array set 204 by virtue of the vertical gap 206.

In the FIG. 4 embodiment of nanowire e-beam characterizing device 100, the array set 202 characterizes the top portion of the e-beam spot 120 as the e-beam spot is displaced transversely across the nanowire e-beam characterizing device 100. The array set 204 characterizes the bottom portion of the e-beam spot 120 as the e-beam spot is displaced relative to the nanowire e-beam characterizing device 100.

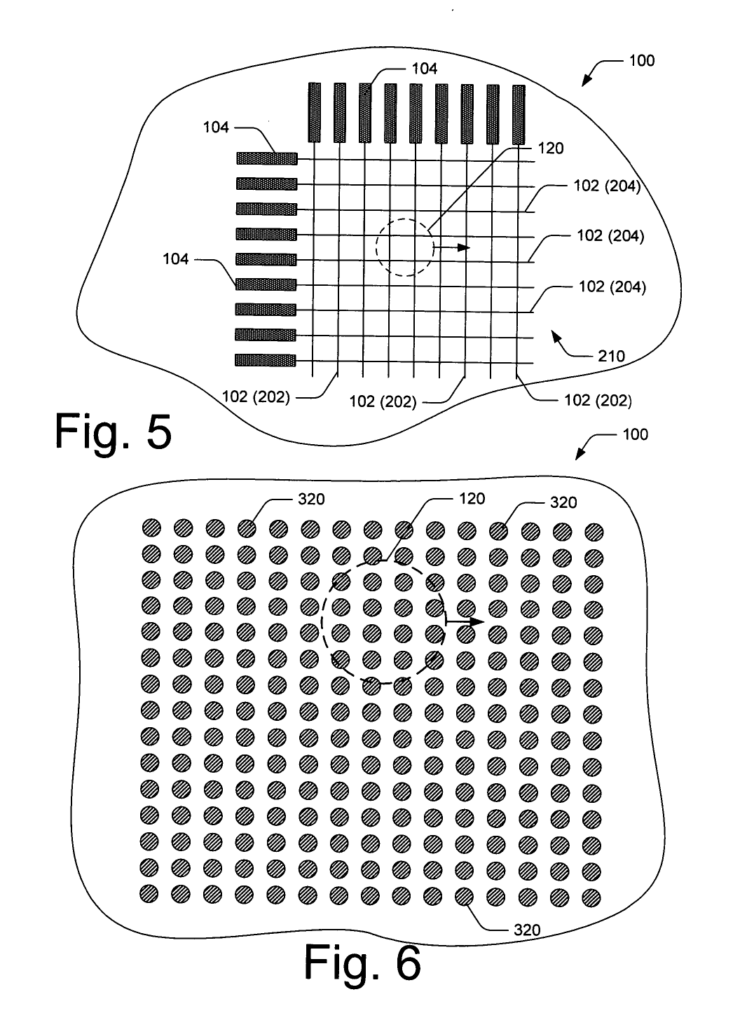

Yet another embodiment of a nanowire e-beam characterizing device 100 includes a square grid array is illustrated in FIG. 5. In this embodiment, the array set 202 of nanowires is arranged substantially perpendicular to the array set 204 of nanowires. The configuration as shown in FIG. 5 provides for an array of individually addressable wires that are arranged in a square grid 210 within the nanowire e-beam characterizing device 100. The embodiment of the nanowire e-beam characterizing device that are arranged in a square grid 210 as illustrated in FIG. 5 (where there are arrays of nanowires that extend both in the X direction and along the Y direction, and cross each other) improves the spatial resolution in both the horizontal (X) and vertical (X) direction compared to those embodiments of characterizing devices that extend in a single array.

In one embodiment of the nanowire e-beam characterizing device having the square grid 210, the individual nanowires from the array set 202 do not contact any of the individual nanowires from the array set 204. Instead, the crossing nanowires 102 are insulatively spaced apart from each other. The nanowires in one array set 204 of nanowires are separated a small distance from each wire of the array set 204 of the nanowires. This spacing of each nanowire in the array set 202 of nanowires from each nanowire in the array set 204 of nanowires can be maintained by, for example, a thin dielectric material or air space. This thin dielectric material can be fashioned as a sheet or strip that extends between the array set 202 and the array set 204. The crossing nanowires are thereby electrically isolated by an air space (not shown) in one embodiment that allows the electrons from the e-beam to physically contact both the horizontally extending nanowires in array 202, and the vertically extending nanowires in array 204.

Similarly, those embodiments of the nanowire e-beam characterizing device 100 that include nanodots 320 arranged in a square array as illustrated in FIG. 6 can improve the spatial resolution to both the X direction and Y direction compared to those embodiments of characterizing devices that extend in a single array.

All of the embodiments of the nanowire e-beam characterizing devices 100 as described relative to FIGS. 1, 3, 4, and 5 include nanowires. As mentioned, the term “nanowires” 102 can include such structures as nanowires, nanotubes, nanodots, and any other nanostructure. Within embodiments of this disclosure, each “nanowire” has at least one dimension that is in the nano-scale.

FIG. 6 shows yet another embodiment of a nanowire e-beam characterizing device 100 that includes an array of nanodots 320. The nanodots 320 are each supplied by the electric components 106, 108, and 110 as described relative to FIG. 1. An array of individually addressable conducting dots is arranged in a square grid that may yield improved spatial resolution. The current is read at each dot, either simultaneously or sequentially. The conducting dots can be electrically connected either by thru wafer methods, or using nanowires protected by layers of dielectric that lead to interconnect pads.

Certain disclosed embodiments of nanowire e-beam characterizing device 100 improve the time resolution of the measurement over so-called scanning knife-edge characterizing devices, one embodiment disclosed in U.S. Pat. No. 4,993,831 that issued on Feb. 19, 1991 to Vandenberg et al. (incorporated herein by reference). This improvement in certain embodiments of the present disclosure occurs by providing a plurality of nanowires, in an array, that can derive a precise one or two-dimensional image of an e-beam at any given time. In one embodiment, the disclosed embodiments of the nanowire e-beam characterizing device 100 have the ability to provide spatial stability information and current stability information simultaneously. Much of the improvement in the precision of the derived image and spatial stability in certain embodiments of the nanowire e-beam characterizing device 100 is due to the high spatial frequency of the nanowires and (nearly) simultaneous reading of the current values from the nanowires via an electrometer or other current measuring device. The spatial resolution of certain embodiments of the nanowire e-beam characterizing device 100 is a function of the width of the nanowires.

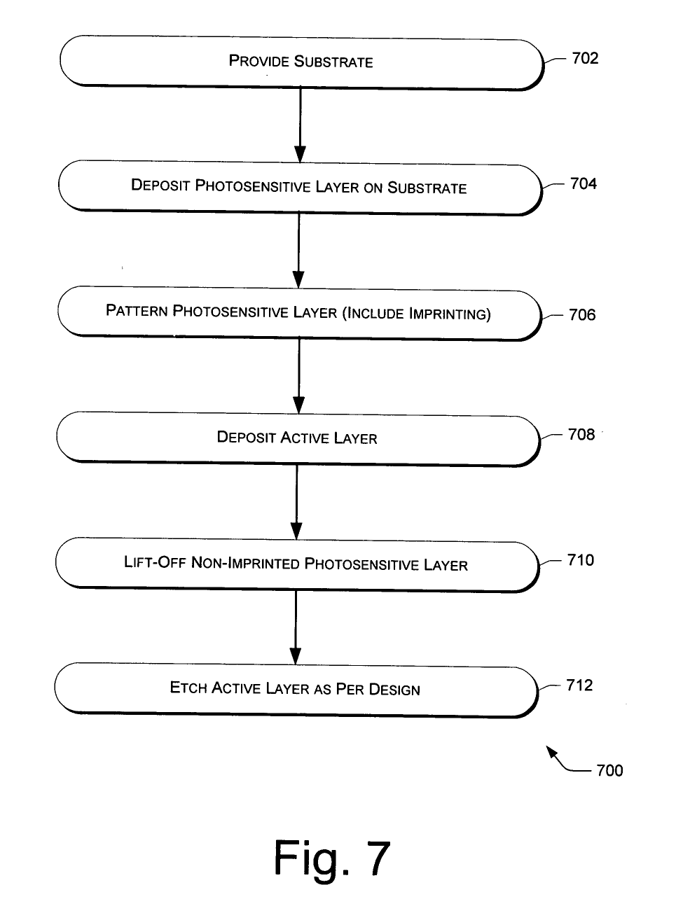

FIG. 7 shows one embodiment of process 700 that is used to produce the embodiments of the nanowire e-beam characterizing device 100 such as shown in FIGS. 1, 3, 4, 5, and 6 based on imprint lithography. The process 700 includes 702, in which a substrate is provided. One embodiment of the imprint lithography process is provided in the commonly assigned U.S. patent application Ser. No. 10/423,063, entitled “Sensor Produced Using Imprint Lithography” to James Stasiak et al. filed Apr. 24, 2003 (incorporated herein by reference). For sake of brevity, the imprint lithography process will not be further described herein.

The substrate forms a platform on which the nanowire e-beam characterizing device 100 can be fabricated. In 704, a photosensitive layer is deposited on the substrate. The photosensitive layer is envisioned to be any layer, such as a polymer layer, that can be deposited the substrate which can be patterned. In 706, the photosensitive layer is patterned by applying a mold to the photosensitive layer. The remaining portions of the photosensitive layer following patterning are hardened. A variety of hardening techniques may be used depending on the type of imprint lithography used (such as thermal imprint lithography and step and flash imprint lithography). The patterning of the polymer layer is consistent with the configuration of the nanowire e-beam characterizing device 100.

Such materials as metals, semiconductors, and superconductors (of the desired conductivity) are deposited on both the imprinted portions and the non-imprinted portions of the photosensitive layer in 708. Those deposited active materials that are deposited in the imprinted portions of the photosensitive material to form an active layer. The height of the imprints of the photosensitive layer is thicker than the deposited active layer so that the deposited active layer is not continuous (the active layer within the imprinted portions of the active layer do not form a contiguous layer with the active layer above the non-imprinted portions of the active layer). The width of the active layer can be selected (down to the nanoscale) based on the dimensions of the imprinted portions of the active layer to provide the desired functionality.

In 710 as shown in FIG. 7, the remaining (non-imprinted) portions of the photosensitive layer and those portions of the active layer deposited on top of the photosensitive layer are then lifted off, leaving the active layer formed in the patterns formed in the photosensitive layer.

The active layer formed on the patterns formed in the photosensitive layer is then etched in 712. The etching can be performed for a duration sufficient to etch the active layer to a desired dimension. In certain embodiments, the active layer can be etched down to nanoscale dimensions. As such, this process allows patterning of the nanowire e-beam characterizing device 100 so certain portions of the active layer can be within the nanoscale within one or two perpendicular cross-sectional dimensions.

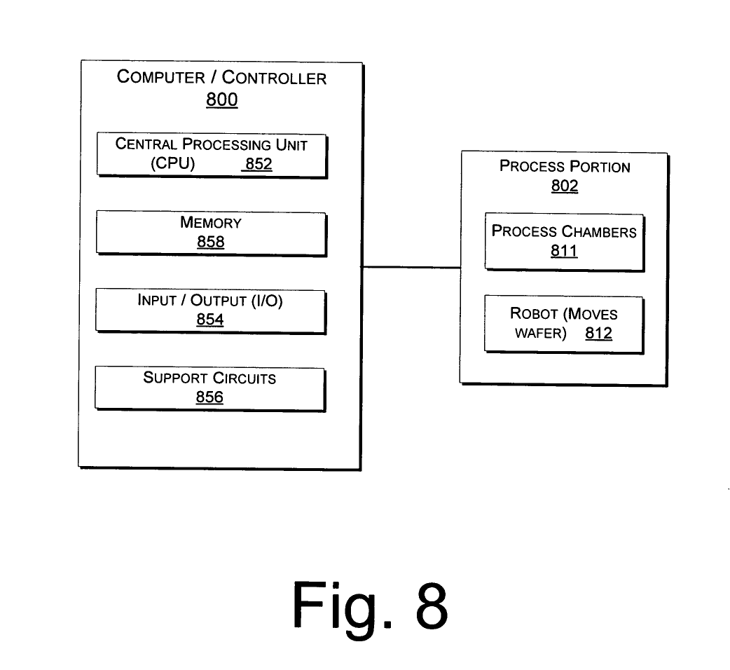

FIG. 8 illustrates one embodiment of a controller or a computer 800 that can control the manufacture of the nanowire e-beam characterizing device 100. A process portion or “fab” is illustrated as 802. The process portion 802 may include a variety of process chambers 811 that the wafer (not shown in drawing) is translated between (often using a robot mechanism 812) to process the nanowire e-beam characterizing device 100 (one embodiment of which is described in this disclosure relative to the process shown in FIG. 7). The particulars of the nanowire e-beam characterizing device 100 vary such that the depth of materials that are deposited and then etched (and the pattern being imprinted and then etched using nano-imprint lithography) depend on the particular application and designer. Such processes as chemical vapor deposition, physical vapor deposition, and electrochemical deposition are known for deposited and/or etching specific materials within the process portion 802.

The controller or the computer 800 comprises a central processing unit (CPU) 852, a memory 858, support circuits 856 and input/output (I/O) circuits 854. The CPU 852 is a general purpose computer which when programmed by executing software contained in memory 858, becomes a specific purpose computer for controlling the hardware components of the processing portion 802. The memory 858 may comprise read only memory, random access memory, removable storage, a hard disk drive, or any form of digital memory device. The I/O circuits comprise well known displays for output of information and keyboards, mouse, track ball, or input of information. Such I/O circuits allow for programming of the controller or computer 800 to determine the processes performed by the process portion 802 (including the associated robot action included in the process portion). The support circuits 856 are well known in the art and include circuits such as cache, clocks, power supplies, and the like.

The memory 858 contains control software that, when executed by the CPU 852, enables the controller or the computer 800 that digitally controls the operation of the various components. In another embodiment, the computer or controller 800 can be analog. For instance, application specific integrated circuits are capable of controlling processes such as occur within the process portion 802.

Although the invention is described in language specific to structural features and methodological steps, it is to be understood that the invention defined in the appended claims is not necessarily limited to the specific features or steps described. Rather, the specific features and steps disclosed represents preferred forms of implementing the claimed invention.

1. An apparatus comprising:
a nanowire e-beam characterizing device including at least one nanowire that is configured to characterize an e-beam, the nanowire has at least one cross-sectional dimension within the nano-scale dimension.

2. The apparatus of claim 1, further comprising:
a power source that is in electrical communication with the at least one nanowire, and
an electrometer that is in electrical communication with the power source.

3. The apparatus of claim 1, wherein the nanowire includes a nanotube.

4. The apparatus of claim 1, wherein the nanowire includes a nanodot.

5. The apparatus of claim 1, wherein the at least one nanowire includes a plurality of nanowires.

6. The apparatus of claim 5, wherein the plurality of nanowires are arranged in an array.

7. The apparatus of claim 6, wherein the plurality of nanowires within the array is substantially contained within a single plane.

8. The apparatus of claim 6, wherein the array is a one-dimensional array.

9. The apparatus of claim 6, wherein the array is a two-dimensional array.

10. The apparatus of claim 6, wherein the array is a three-dimensional array.

11. The apparatus of claim 1, wherein the nanowire is arranged in a substantially parallel array set of nanowires.

12. The apparatus of claim 11, wherein the substantially parallel array set of nanowires includes a first array set of nanowires and a second array set of nanowires.

13. The apparatus of claim 12, wherein the first array set of nanowires overlaps with the second array set of nanowires.

14. The apparatus of claim 12, wherein the first array set of nanowires does not overlap with the second array set of nanowires.

15. The apparatus of claim 1, wherein the nanowire e-beam characterizing device is incorporated within an e-beam based storage device.

16. The apparatus of claim 1, further comprising a pad that is in electrical communication with the nanowire, and wherein the power source is in electrical communication with the pad.

17. A computer readable medium having computer executable instructions that when performed by a processor performs a process, the process comprising:
making at least one nanowire, the nanowire has at least one cross-sectional dimension within the nano-scale dimension, wherein the nanowire is configured to characterize an e-beam.

18. The computer readable medium that can perform the process of claim 17, further comprising:
forming a power source that is in electrical communication with the nanowire, and
forming an electrometer that is in electrical communication with the power source.

19. The computer readable memory that can perform the process of claim 17, wherein the at least one nanowire includes a plurality of nanowires, different ones of the plurality of nanowires extend in two substantially perpendicular cross-sectional directions.

20. A method, comprising:
forming an e-beam characterizing device including
forming at least one nanowire, the nanowire has at least one cross-sectional dimension within the nano-scale dimension,
providing a power source that is in electrical communication with the nanowire, and
providing an electrometer that is in electrical communication with the power source.

21. The method of claim 20, wherein the nanowire includes a nanotube.

22. The method of claim 20, wherein the nanowire includes a nanodot.

23. The method of claim 20, wherein the forming the at least one nanowire includes forming a plurality of nanowires, each one of the nanowires is formed to have at least one cross-sectional dimension within the nano-scale dimension.

24. The method of claim 23, wherein the plurality of nanowires are arranged in an array.

25. The method of claim 23, wherein the array is substantially contained within a single plane.

26. The method of claim 24, wherein the array is a one-dimensional array.

27. The method of claim 24, wherein the array is a two-dimensional array.

28. The method of claim 24, wherein the array is a three-dimensional array.

29. The method of claim 20, wherein the at least one nanowire includes a plurality of nanowires that are arranged in a substantially parallel array as a set of nanowires.

30. The method of claim 29, wherein the substantially parallel array set of nanowires includes a first array set of nanowires and a second array set of nanowires.

31. The method of claim 30, wherein the first array set of nanowires overlaps with the second array set of nanowires.

32. The method of claim 30, wherein the first array set of nanowires does not overlap with the second array set of nanowires.

33. The method of claim 20, wherein the nanowire e-beam characterizing device is incorporated within an e-beam based storage device.

34. The method of claim 20, further comprising a pad that is in electrical communication with the nanowire, and wherein the power source is in electrical communication with the pad.

35. An apparatus comprising:
a nanowire gas ion beam characterizing device including a nanowire that is configured to characterize a gas ion beam, the nanowire has at least one cross-sectional dimension within the nano-scale dimension.
